(19) United States
(12) Patent Application Publication
(10) Pub. No.: US 2024/0266227 A1
(43) Pub. Date: Aug. 8, 2024

(54) FIN FIELD-EFFECT TRANSISTOR AND METHOD OF FORMING THE SAME

(71) Applicant: Taiwan Semiconductor Manufacturing Company, Ltd., Hsinchu (TW)

(72) Inventors: Wei-Liang Lu, Zhubei City (TW); Chang-Yin Chen, Hsinchu City (TW); Jian-Hsuan Zheng, Zhudong Township (TW); Che-Cheng Chang, Cupertino, CA (US)

(73) Assignee: Taiwan Semiconductor Manufacturing Company, Ltd., Hsinchu (TW)

(21) Appl. No.: 18/165,624

(22) Filed: Feb. 7, 2023

(51) Int. Cl. H01L 21/8238; H01L 27/092; H01L 29/10; H01L 29/66

(52) U.S. Cl. CPC H01L 21/823821; H01L 21/823807; H01L 21/823814; H01L 21/823878; H01L 27/0924; H01L 29/1037; H01L 29/66545

(57) ABSTRACT

A method of fabricating a semiconductor structure includes forming a semiconductor fin over a substrate. The method includes forming a semiconductor fin over a substrate. The method includes forming an isolation region around the semiconductor fin. The method includes forming a dummy gate structure over the semiconductor fin, which further includes performing a first etching process using a first etchant and subsequently performing a second etching process using a second etchant, where the first etchant is different from the second etchant in composition. The method includes forming source/drain features adjacent the dummy gate structure. The method includes replacing the dummy gate structure with a metal gate structure that is interposed between the source/drain features.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

Fin Field-Effect Transistor (FinFET) devices are becoming commonly used in integrated circuits. FinFET devices have a three-dimensional structure that comprises a fin protruding from a substrate. A gate structure, configured to control the flow of charge carriers within a conductive channel of the FinFET device, wraps around the fin. For example, in a FinFET device, the gate structure wraps around three sides of the fin, thereby forming conductive channels on three sides of the fin. While methods of fabricating gate structures in FinFET devices have been generally adequate, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a three-dimensional perspective view of a fin field-effect transistor (FinFET) device, in accordance with some embodiments.

FIGS. 2 and 3 each illustrate a flow chart of an example method for making a FinFET device, in accordance with some embodiments.

FIGS. 4, 5, 6, 7, 8, 9, and 10 illustrate cross-sectional views of the FinFET device of FIG. 1 along cross-section L-L′ during intermediate stages of the method illustrated in FIGS. 2 and/or 3, in accordance with some embodiments.

FIGS. 11A, 12A, 13A, 14A, 15A, 16A, 17A, and 22A illustrate cross-sectional views of the FinFET device of FIG. 1 along cross-section A-A′ during intermediate stages of the method illustrated in FIGS. 2 and/or 3, in accordance with some embodiments.

FIGS. 11B, 12B, 13B, 14B, 15B, 16B, 17B, and 22B illustrate cross-sectional views of the FinFET device of FIG. 1 along cross-section B-B′, corresponding to FIGS. 11A, 12A, 13A, 14A, 15A, 16A, 17A, and 22A, respectively, during intermediate stages of the method illustrated in FIGS. 2 and/or 3, in accordance with some embodiments.

FIGS. 11C, 12C, 13C, 14C, 15C, 16C, 17C, and 22C illustrate cross-sectional views of the FinFET device of FIG. 1 along cross-section C-C′, corresponding to FIGS. 11A, 12A, 13A, 14A, 15A, 16A, 17A, and 22A, respectively, during intermediate stages of the method illustrated in FIGS. 2 and/or 3, in accordance with some embodiments.

FIGS. 18, 19, 20, and 21 illustrate cross-sectional views of the FinFET device 100 along the cross-section D-D′ during intermediate stages of the method illustrated in FIGS. 2 and/or 3, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments of the present disclosure are generally directed to a structure, and a method of forming, a FinFET device, and in particular, in the context of forming tuning sidewall profiles of a dummy gate structure before implementing a gate replacement process. In some embodiments, the FinFET device provided herein may be configured as an N-type FET device, a P-type FET device, a complementary FET device. Applications of the FinFET device of the present disclosure include, but are not limited to, logic devices, RO devices, memory devices (e.g., static random-access memory, or SRAM), and other suitable devices.

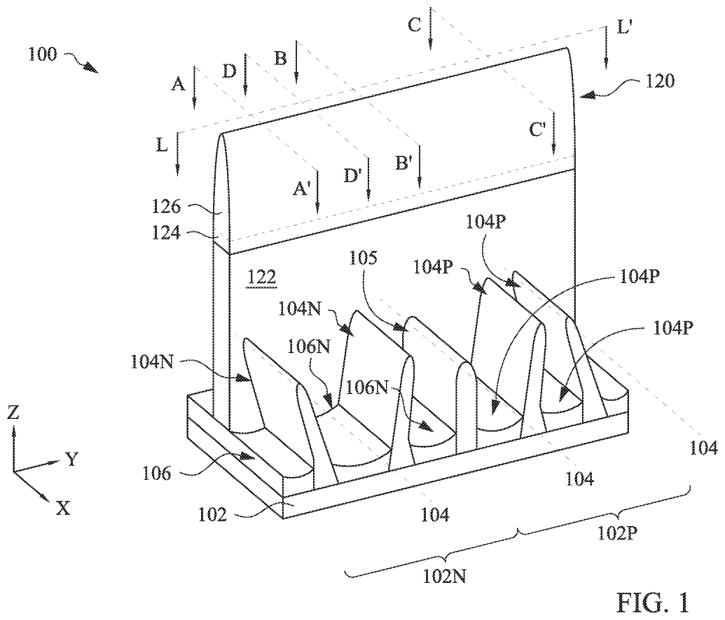

FIG. 1 illustrates a perspective view of an example FinFET device 100, in accordance with various embodiments. The FinFET device 100 includes a substrate 102 having a device region 102N adjacent a device region 102P. The FinFET device 100 includes a plurality of semiconductor fins 104N and 104P and dielectric fins 105 extending from the substrate 102 along the Z direction. In the present embodiments, each dielectric fin 105 generally extends along a boundary between the device regions 102N and 102P along the X direction. The semiconductor fins 104N and 104P and the dielectric fins 105 are generally oriented longitudinally along the X direction and spaced from each other along the Y direction.

Isolation regions 106 are disposed over the substrate 102 to separate neighboring semiconductor fins 104N and 104P and dielectric fins 105. The isolation regions 106 include a portion (or region) 106N in the device region 102N and a portion (or region) 106P in the device region 102P. The FinFET device 100 further includes a dummy gate structure (or placeholder gate) 120 disposed over the semiconductor fins 104N and 104P and the dielectric fins 105 and generally oriented longitudinally along the Y direction, i.e., substantially perpendicular to the semiconductor fins 104N and 104P and the dielectric fins 105. In the present embodiments, the dummy gate structure 120 includes at least a gate layer 122, a dielectric layer 124 over the gate layer 122, and a dielectric layer 126 over the dielectric layer 124. Line 140 extending along the X direction indicates a position of the fin top (FT) of each of the semiconductor fins 104N and 104P and the dielectric fins 105 with respect to a height of the dummy gate structure 120.

FIG. 1 is provided as a reference to illustrate a number of cross-sections in subsequent figures. For example, cross-section L-L′ extends along a longitudinal axis of the dummy gate structure 120 of the FinFET device 100; cross-section A-A′ extends perpendicular to the longitudinal axis of the dummy gate structure 120 and between two neighboring semiconductor fins 104N; cross-section B-B′ extends perpendicular to the longitudinal axis of the dummy gate structure 120 and between a semiconductor fin 104N and a dielectric fin 105; cross-section C-C′ extends perpendicular to the longitudinal axis of the dummy gate structure 120 and between two neighboring semiconductor fins 104P; and cross-section D-D′ extends across the longitudinal axis of the dummy gate structure 120 and along a longitudinal axis of the semiconductor fin 104N in a direction of, for example, a current flow between subsequently-formed source/drain regions of the semiconductor fin 104N. Subsequent figures refer to these reference cross-sections for clarity.

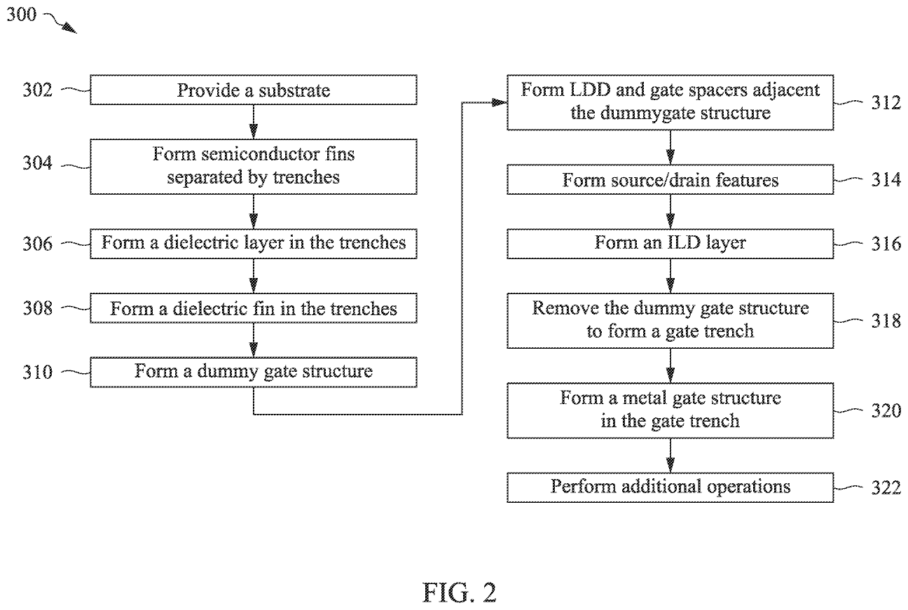

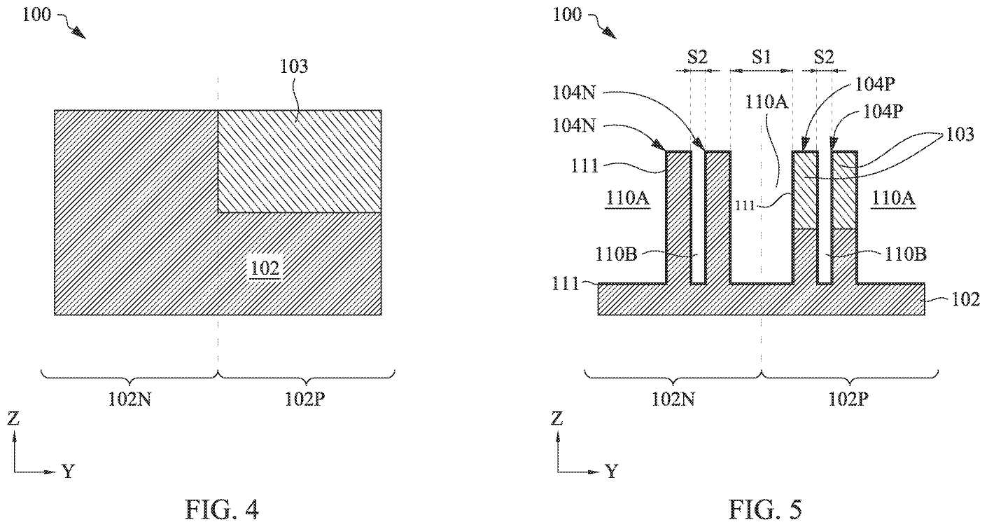

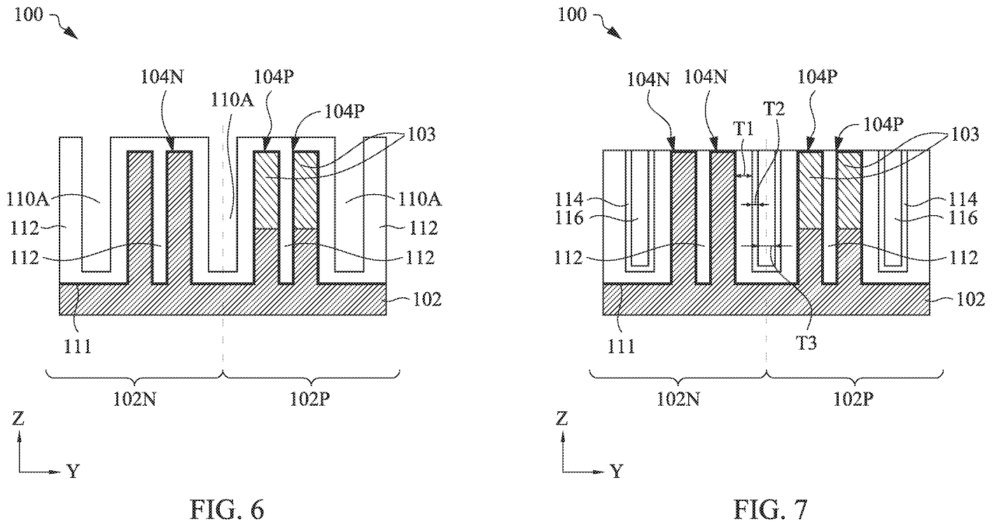

FIG. 2 illustrates a flowchart of a method 300 for forming a non-planar transistor device, according to one or more embodiments of the present disclosure. For example, at least some of the operations of the method 300 can be used to form a FinFET device (e.g., the FinFET device 100), a nano-sheet (or gate-all-around) transistor device, a nanowire transistor device, a vertical transistor, or the like. It is noted that the method 300 is merely an example, and is not intended to limit the present disclosure. Accordingly, it is understood that additional operations may be provided before, during, and after the method 300 of FIG. 2, and that some other operations may only be briefly described herein. In some embodiments, operations of the method 300 may be associated with cross-sectional views of the example FinFET device 100 at various fabrication stages as shown in FIGS. 4-22C, which will be discussed in further detail below.

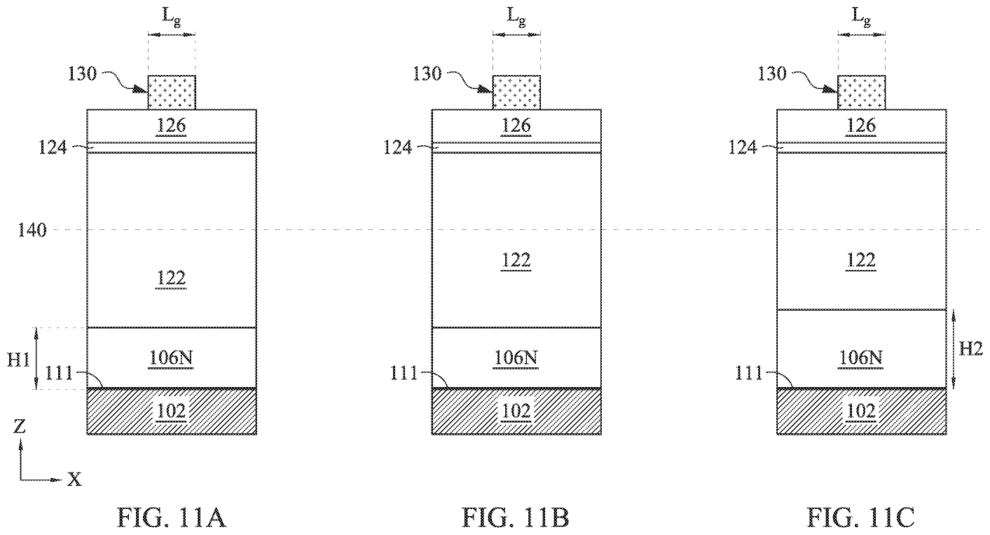

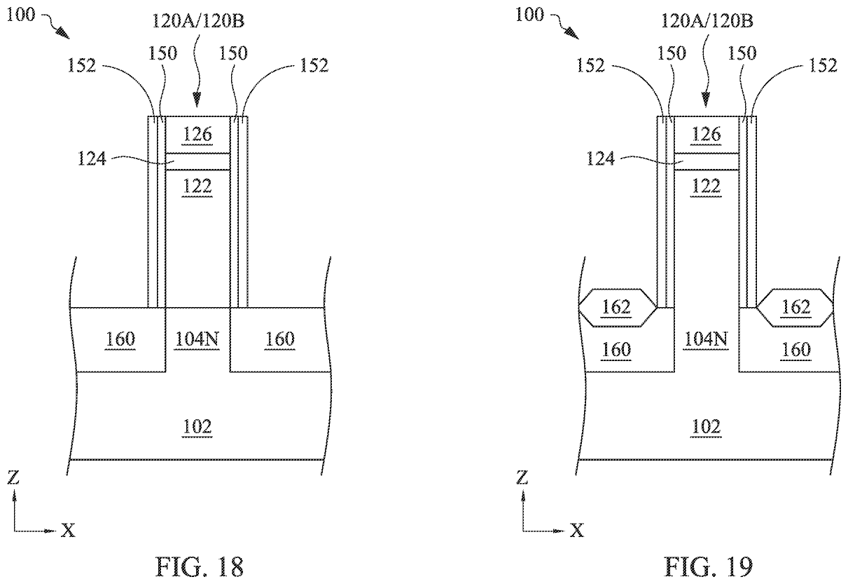

As mentioned above, FIGS. 4-22C illustrate, in various cross-sectional views indicated in FIG. 1, a portion of a FinFET device 100 at various fabrication stages of the method 300 of FIG. 2. For example, FIGS. 4-10 illustrate cross-sectional views of the FinFET device 100 along the cross-section L-L′; FIGS. 11A, 12A, 13A, 14A, 15A, 16A, 17A, and 22A illustrate cross-sectional views of the FinFET device 100 along the cross-section A-A′; FIGS. 11B, 12B, 13B, 14B, 15B, 16B, 17B, and 22B illustrate cross-sectional views of the FinFET device 100 along the cross-section B-B′; FIGS. 11C, 12C, 13C, 14C, 15C, 16C, 17C, and 22C illustrate cross-sectional views of the FinFET device 100 along the cross-section C-C′; and FIGS. 18, 19, 20, and 21 illustrate cross-sectional views of the FinFET device 100 along the cross-section D-D′. Although FIGS. 4-22C illustrate the FinFET device 100, it is understood the FinFET device 100 may include a number of other devices such as inductors, fuses, capacitors, coils, etc., which are not shown in FIGS. 4-22C, for purposes of clarity of illustration. Still further, although the present embodiments depict the FinFET device 100 to include a pair of the semiconductor fins 104N, a pair of the semiconductor fins 104P, and a dielectric fin 105 therebetween, it is understood the FinFET device 100 may include a number of the semiconductor fins and dielectric fins arranged in such and/or other configurations suitable for providing various devices according to specific design requirements.

Referring to FIGS. 1, 2, and 4, the method 300 at operation 302 provides the substrate 102. The substrate 102 may be a semiconductor substrate, such as a bulk semiconductor, a semiconductor-on-insulator (SOI) substrate, or the like, which may be doped (e.g., with a p-type or an n-type dopant) or undoped. The substrate 102 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 102 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

Referring to FIGS. 1, 2, and 5, the method 300 at operation 304 forms the semiconductor fins 104N and 104P over the device region 102N and 102P, respectively.

In the present embodiments, the semiconductor fins 104N and 104P are configured to form devices of different conductivity types. For example, the semiconductor fins 104N may be configured to form an N-type FinFET device in the device region 102N and the semiconductor fins 104P may be configured to form a P-type FinFET device in the device region 102P. In this regard, the semiconductor fins 104N and 104P may be formed of different semiconductor materials as discussed in detail below. Furthermore, although two semiconductor fins 104N are formed in the device region 102N and two semiconductor fins 104P are formed in the device region 102P, it is understood that any number of the semiconductor fins 104N and 104P may be formed in their respective device regions according to specific design requirements. For example, two semiconductor fins 104N may be formed in the device region 102N and one semiconductor fin 104P may be formed in the adjacent device region 102P

For embodiments in which the semiconductor fins 104N and 104P are configured to provide an N-type FinFET device and a P-type FinFET device, respectively, the semiconductor fin 104N includes silicon and the semiconductor fin 104P includes silicon germanium. In some embodiments, the semiconductor fin 104N is free from germanium. In some embodiments, forming the semiconductor fins 104N and 104P includes first patterning the substrate 102 to form a silicon germanium layer 103 in the device region 102P. The substrate 102 may be patterned using, for example, photolithography and etching techniques. For example, a mask layer (not depicted) may be formed over the substrate 102 and patterned using photolithography techniques. Generally, photolithography techniques utilize a photoresist material (not shown) that is deposited, irradiated (exposed), and developed to remove a portion of the photoresist material. The remaining photoresist material protects the underlying material, such as the mask layer in this example, from subsequent processing steps, such as etching. Subsequently, the patterned mask layer is used to pattern the substrate 102 and form a recess (not depicted) in the device region 102P. Thereafter, the silicon germanium layer 103 may be epitaxially grown to fill the recess, and the substrate 102 and the silicon germanium layer 103 may be planarized by etching or polishing (e.g., chemical-mechanical polishing, or CMP) to form the patterned substrate 102 as depicted in FIG. 4.

Subsequently, the patterned substrate 102 is further patterned to form the semiconductor fins 104N in the device region 102N and the semiconductor fins 104P in the device region 102P. In some embodiments, a mask layer (not depicted) including a first dielectric layer and a second dielectric layer over the first dielectric layer may be formed over the patterned substrate 102. The mask layer may function as a protective layer overlaying the patterned substrate 102 (i.e., the resulting semiconductor fins 104N and 104P) form subsequent processing. In some examples, the first and the second dielectric layers differ in composition and may each include silicon oxide, silicon nitride, silicon oxynitride, silicon carbonitride, the like, or combinations thereof. The first and the second dielectric layers may be formed using any suitable method, such as chemical vapor deposition (CVD), atomic layer deposition (ALD), low-pressure chemical vapor deposition (LPCVD), plasma enhanced chemical vapor deposition (PECVD), the like, or combinations thereof.

The mask layer may be patterned to form a patterned mask using photolithography and etching techniques, such as those discussed above with respect to patterning the substrate 102. Subsequently, the patterned mask is used to pattern the substrate 102 (including the silicon germanium layer 103) and define the semiconductor fins 104N and 104P as shown in FIG. 5. In the present embodiments, the semiconductor fins 104N and 104P are separated by trenches of different spacings. For example, the two semiconductor fins of different conductivity types may be separated by a wider trench 110A have a spacing S1 (i.e., a fin spacing S1), and the two semiconductor fins of the same conductivity type may be separated by a narrower trench 110B having a spacing S2 (i.e., a fin spacing S2). In some embodiments, forming the semiconductor fins 104N and 104P includes etching the trenches 110A and 110B in the substrate 102 using, for example, dry etch, wet etch, reactive ion etch (RIE), neutral beam etch (NBE), the like, or combinations thereof. The etching process may be anisotropic. In some embodiments, the trenches 110A and 110B may be strips (viewed from the top) substantially parallel to each other and closely spaced with respect to each other. In some embodiments, the trenches 110A and 110B may be continuous and surround the semiconductor fins 104N and 104P.

In some embodiments, the semiconductor fins 104N and 104P may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers, or mandrels, may then be used to pattern the semiconductor fins 104N and 104P.

Thereafter, a silicon liner 111 is formed conformally over the semiconductor fins 104N and 104P and portions of the substrate 102. The silicon liner 111 may be epitaxially grown on the semiconductor fins 104N and 104P and the substrate 102 using any suitable method, such as CVD, vapor phase epitaxy (VPE), liquid phase epitaxy (LPE), metal-organic CVD (MOCVD), selective epitaxial growth (SEG), molecular beam epitaxy (MBE), or the like. Alternatively, the silicon liner may be deposited using a suitable method, such as CVD, ALD, or the like.

Referring to FIGS. 1, 2, 6, the method 300 at operation 306 forms a dielectric layer 112 in the trenches 110A and 110B.

In the present embodiments, the dielectric layer 112 is configured to electrically isolate neighboring fins (e.g., semiconductor fins 104N and 104P) from each other, and may include an oxide, such as silicon oxide, a low-k dielectric material, such as phosphosilicate glass (PSG), borosilicate glass (BSG), boron-doped phosphosilicate glass (BPSG), and undoped silicate glass (USG), the like, or combinations thereof. The dielectric layer 112 may be formed by CVD, ALD, high density plasma CVD (HDPCVD), flowable CVD (FCVD) (e.g., a CVD-based material deposition in a remote plasma system and post curing to make it convert to another material, such as an oxide), spin-coating, the like, or combinations thereof. Other dielectric materials and/or other formation processes may be used. In the illustrated embodiment, the dielectric layer 112 includes silicon oxide formed by a FCVD process. An annealing process may be performed once the dielectric material is formed to cure the dielectric material. A planarization process, such as a CMP process, may be implemented to remove any excess dielectric material from top surfaces of the semiconductor fins 104N and 104P. In some examples, as depicted, the CMP process may be implemented at a subsequent operation.

In some embodiments, a dielectric material is deposited in the trenches 110A and 110B to form the dielectric layer 112 conformally using a method such as CVD, ALD, or the like. Due to their narrower widths, the trenches 110B may be completely filled by the dielectric layer 112, while the trenches 110A remain over the dielectric layer 112.

In alternatively embodiments, the dielectric material is deposited to fill the trenches 110A and 110B and subsequently recessed to form the dielectric layer 112. In this regard, portions of the trenches 110A and 110B may be re-exposed upon recessing the dielectric material. In some embodiments, recessing the dielectric material forms the dielectric layer 112 as shallow trench isolation (STI) regions between adjacent semiconductor fins 104N and 104P. Respective top surfaces of the dielectric layer 112 between adjacent semiconductor fins 104N and 104P may have a flat surface (as depicted), a convex surface (not depicted), a concave surface (such as dishing; not depicted)), or combinations thereof, that may be formed by an appropriate etch. The dielectric layer 112 may be recessed using an acceptable etching process, such as one that is selective to the material of the dielectric layer 112 with respect to the silicon liner 111 and the semiconductor fins 104N and 104P. For example, a dry etch or a wet etch using dilute hydrofluoric (DHF) acid may be performed to recess the dielectric layer 112.

Referring to FIGS. 1, 2, and 7-9, the method 300 at operation 308 forms the dielectric fin 105 over the dielectric layer 112.

Referring to FIG. 7, forming the dielectric fin 105 includes first forming a dielectric layer 114 over the dielectric layer 112. In some embodiments, the dielectric layer 114 includes silicon oxide, silicon nitride, silicon oxynitride, silicon carbonitride, the like, or combinations thereof. In some embodiments, the dielectric layer 114 includes a composition different from that of the dielectric layer 112 to ensure sufficient etching selectivity therebetween. For example, the dielectric layer 112 may include an oxide material, such as silicon oxide, and the dielectric layer 114 may include a nitride material, such as silicon nitride. The dielectric layer 114 may be formed conformally by a suitable deposition method, such as CVD, ALD, LPCVD, PECVD, HDPCVD, the like, or combinations thereof. In the present embodiments, the dielectric layer 114 is formed to partially fill the trenches 110A.

Subsequently, a dielectric layer 116 is formed to fill the trenches 110A and over the dielectric layer 114. In some embodiments, the dielectric layer 116 includes silicon oxide, silicon nitride, silicon oxynitride, silicon carbonitride, a low-k dielectric material, such as PSG, BSG, BPSG, USG, the like, or combinations thereof. In some embodiments, the dielectric layer 116 includes a composition different from that of each of the dielectric layer 112 and the dielectric layer 114 to ensure sufficient etching selectivity therebetween. For example, the dielectric layer 112 may include an oxide material, such as silicon oxide, the dielectric layer 114 may include a nitride material, such as silicon nitride, and the dielectric layer 116 may include an oxide material different from the oxide material of the dielectric layer 112.

In some embodiments, a thickness T3 of the dielectric layer 116 is less than each of a thickness T1 of the dielectric layer 112 and a thickness T2 of the dielectric layer 114. In some embodiments, the thickness T3 is greater than each of the thickness T1 and the thickness T2. In some embodiments, the thickness T1 is greater than each of the thickness T2 and the thickness T3.

In the present embodiments, the dielectric layer 116 is formed to completely fill the trenches 110A. In some embodiments, the dielectric layer 116 may be deposited using FCVD and subsequently subjected to a thermal treatment (e.g., a curing process). One or more CMP processes are then performed to the FinFET device 100 to remove portions of the dielectric layers 112, 114, and/or 116 formed over the top surfaces of the semiconductor fins 104N and 104P as shown in FIG. 7.

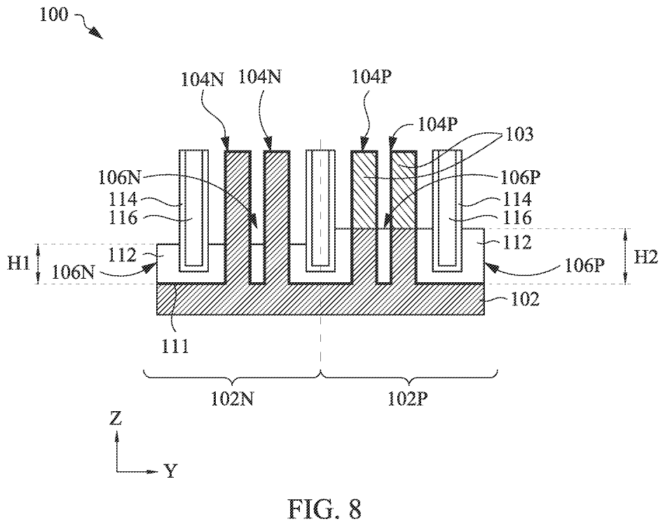

Referring to FIG. 8, after performing the CMP process(es), the dielectric layer 112 is partially recessed, such that its top surface is below the top surfaces of the semiconductor fins 104N and 104P as well as the top surfaces of the dielectric layers 114 and 116. In the present embodiments, the dielectric layer 112 is selectively recessed with respect to the dielectric layers 114 and 116 by a suitable etching process, such as dry etch, wet etch, RIE, the like, or combinations thereof. Accordingly, the semiconductor fins 104N and 104P and the dielectric layers 114 and 116 extend above the recessed dielectric layer 112, which is hereafter referred to as the isolation regions 106, and the dielectric layers 114 and 116 together form the dielectric fin 105.

In some embodiments, the isolation regions 106 in the device region 102N (e.g., surrounding the semiconductor fins 104N) is recessed more than the isolation regions 106 in the device region 102P (e.g., surrounding the semiconductor fins 104P), such that the portion 106N has a step height H1 that is less than a step height H2 of the portion 106P, where the step height H1 and H2 are each measured from a top surface of the substrate 102 to a top surface of the respective portion of the isolation regions 106. As will be discussed in detail below, the difference between the step height H1 and the step height H2 may lead to disparity in etchant loading during the patterning of the dummy gate structure 120, causing differences in sidewall profile of the dummy age structure 120 over the fins (i.e., semiconductor and/or dielectric fins) in the device region 102N and the device region 102P.

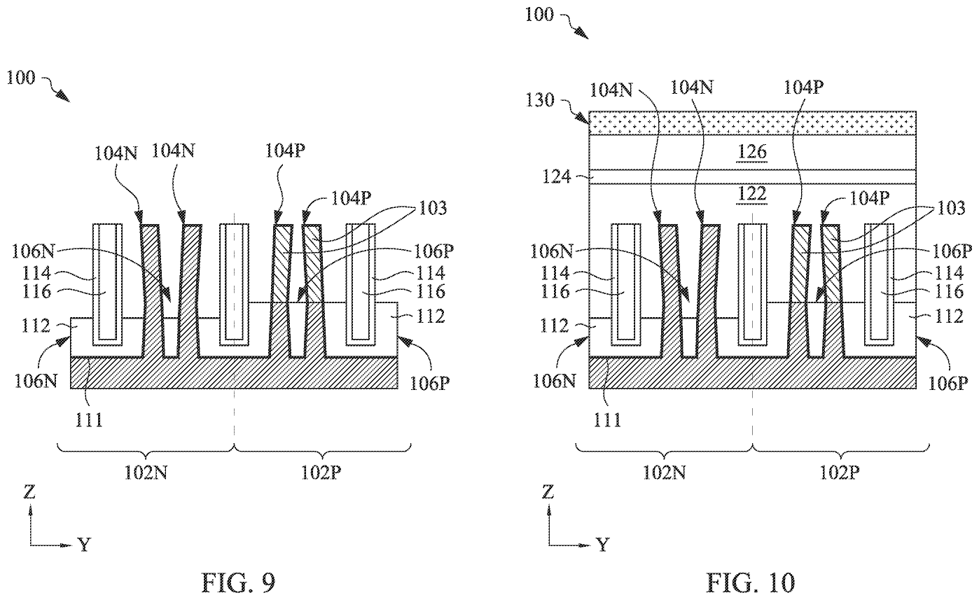

In some embodiments, referring to FIG. 9, curing the dielectric layer 116 may cause shrinkage in the isolation regions 106, which may exert stress on the nearby material layers, leading to bending of the semiconductor fins 104N and 104P. Due to differences in crystal structure between silicon and silicon germanium, the stress may cause the semiconductor fins 104N to bend outward, i.e., away from one another and toward a neighboring dielectric fin 105, and the semiconductor fins 104P to bend inward, i.e., toward one another and away from a neighboring dielectric fin 105. In some instances, such bending may alter the spacing between adjacent semiconductor fins, further affecting the extent of etchant loading during the subsequent patterning process.

Referring to FIGS. 1-3 and 10-17C, the method 300 at operation 310 forms the dummy gate structure 120 over the FinFET device 100, thereby defining a channel region in each of the semiconductor fins 104N and 104P. The dummy gate structure 120 may include the gate layer 122, the dielectric layer 124 over the gate layer 122, and the dielectric layer 126 over the dielectric layer 124. Other material layers, such as an interfacial layer, a gate dielectric layer, a capping layer, and/or other suitable layers may be formed in the dummy gate structure 120.

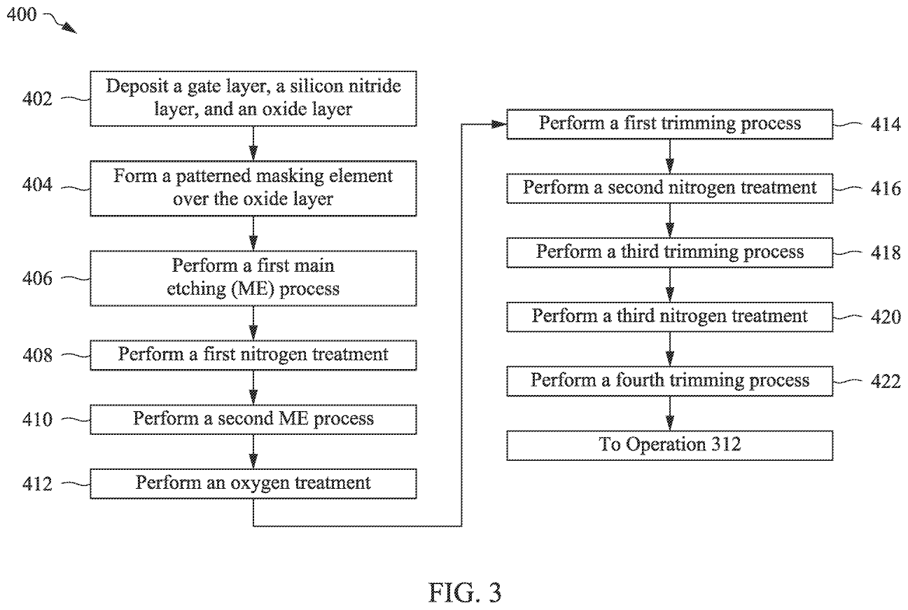

Operation 310 of the method 300 may be implemented by a method 400 as illustrated by a flow chart in FIG. 3, according to one or more embodiments of the present disclosure. It is noted that the method 400 is merely an example, and is not intended to limit the present disclosure. Accordingly, it is understood that additional operations may be provided before, during, and after the method 400 of FIG. 3, and that some other operations may only be briefly described herein. In some embodiments, operations of the method 400 may be associated with cross-sectional views of the example FinFET device 100 at various fabrication stages as shown in FIGS. 10-17C, which will be discussed in further detail below. It should be appreciated that, although one dummy gate structure 120 is shown in reference to the discussion of the method 400, more or less dummy gate structures can be formed over the substrate 102, while remaining within the scope of the present disclosure.

Referring to FIGS. 3 and 10, the method 400 at operation 402 forms the gate layer 122, the dielectric layer 124, and the dielectric layer 126 over the substrate 102.

The gate layer 122 may include, for example, polysilicon, although other materials may also be used. In some embodiments, the dielectric layer 124 and the dielectric layer 126 are collectively referred to as a mask layer and may each include a suitable material, such as silicon oxide, silicon nitride, silicon oxynitride, silicon carbonitride, the like, or combinations thereof. In the present embodiments, the dielectric layers 124 and 126 differ in composition to accommodate the patterning of the gate layer 122. In some embodiments, the dielectric layer 124 includes a nitride material and the dielectric layer 126 includes an oxide material. The gate layer 122, the dielectric layer 124, and the dielectric layer 126 may each be formed by any suitable method, such as CVD, ALD, PVD, the like, or combinations thereof, and planarized using CMP, for example.

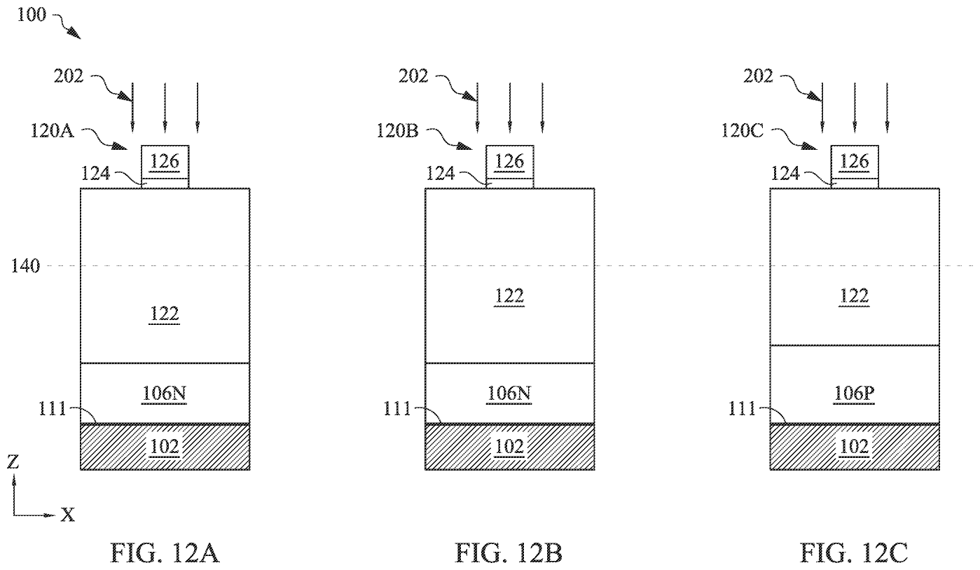

Subsequently, referring to FIGS. 3 and 10-11C, the method 400 at operation 404 forms a patterned mask (including a photoresist layer, for example) 130 over the dielectric layer 126 (and the underlying material layers). It is noted that FIGS. 11A-11C (and subsequent FIGS. 12A-17C) illustrate cross-sections of portions 120A, 120B, and 120C, respectively, of the dummy gate structure 120 as shown in FIG. 1.

The patterned mask 130 may be formed by photolithography and etching techniques similar to that discussed above with respect to patterning the substrate 102. The patterned mask 130 exposes portions of the dielectric layer 126, dielectric layer 124, and the gate layer 122 to be removed from the FinFET device 100 to form the dummy gate structure 120 as shown in FIG. 1, for example. In this regard, the patterned mask 130 has a width L_{g} along the X direction, which may be considered a critical dimension (CD) for the dummy gate structure 120, that defines a gate length of the dummy gate structure 120. In the present embodiments, the patterned mask 130 extends longitudinally along the Y axis, i.e., perpendicular to the longitudinal direction of the semiconductor fins 104N and 104P.

Referring to FIGS. 3 and 12A-12C, the method 400 at operation 406 performs a main etching (ME) process 202 to pattern the dielectric layers 126 and 124 using the patterned mask 130 as an etch mask.

In the present embodiments, the ME process 202 is implemented as a dry etching or an RIE process to achieve anisotropic, or substantially anisotropic, sidewalls on at least top portions of the dielectric layers 126 and 124. The ME process 202 may be performed using one or more etching gases selected from a fluorine-containing gas (e.g., CₓH_{y}F_{z}, where x>0, y≥0, and z>0, such as CF₄, CHF₃, CH₂F₂, or CH₃F, C₄F₆, SF₆, NF₃, the like, or combinations thereof), a chlorine-containing gas (e.g., Cl₂, BCl₃, the like, or a combination thereof), a bromine-containing gas (e.g., HBr), O₂, H₂, the like, or combinations thereof. In an example embodiments, the ME process 202 is implemented using a combination of etching gases including CF₄, HBr, and O₂. The combination of etching gases may be determined based on compositions of the gate layer 122 and the dielectric layers 126 and 124.

Still referring to FIGS. 3 and 12A-12C, the method 400 at operation 408 performs a N₂-based atomic layer treatment (ALT) to smooth and protect the etched sidewalls of the dielectric layers 126 and 124. In some embodiments, N₂ reacts with etching by-product(s) to form polymers on the etched sidewalls to limit any lateral over-etching of the ME process 202, thereby maintaining the sidewall profile of the patterned material layers. The N₂ ALT may be implemented concurrently with and/or subsequently to the ME process 202.

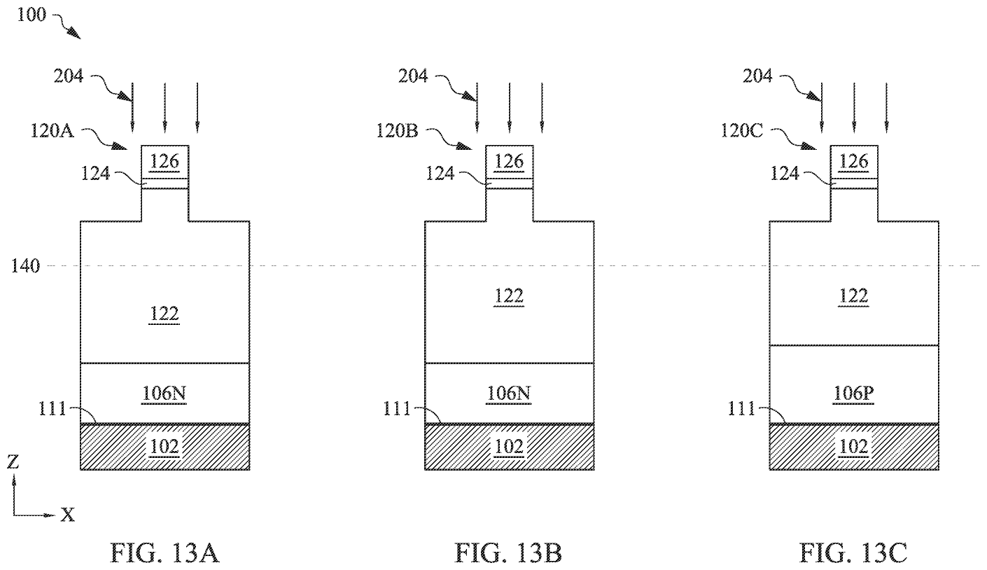

Referring to FIGS. 3 and 13A-13C, the method 400 at operation 410 performs an ME process 204 to etch a top portion of the gate layer 122 using the patterned dielectric layer 124 as an etch mask.

In the present embodiments, the ME process 204 is similar to the ME process 204 in that it is implemented as a dry etching or an RIE process to achieve substantially anisotropic sidewalls on the gate layer 122. In this regard, the ME process 204 may be performed using one or more etching gases selected from a fluorine-containing gas, a chlorine-containing gas, a bromine-containing gas, O₂, H₂, the like, or combinations thereof, as discussed in detail above. In some embodiments, the ME process 204 is implemented using the same etching gases as the ME process 202, which includes CF₄, HBr, and O₂. However, various etching parameters of the ME process 204 may differ from those of the ME process 202. For example, as the ME process 204 advances the patterning of the dummy gate structure 120, parameters of the ME process 204 may be adjusted to maintain a substantially vertical profile of the etched sidewalls of the gate layer 122. In this regard, the amount (or flux) of Oz as an etching gas may increase for the ME process 204 in comparison to the ME process 202. Additionally, parameters of the ME process 204 may also be adjusted as the etching process approaches the fin top (or line) 140 to avoid inadvertent damage to the semiconductor fins 104N and 104P.

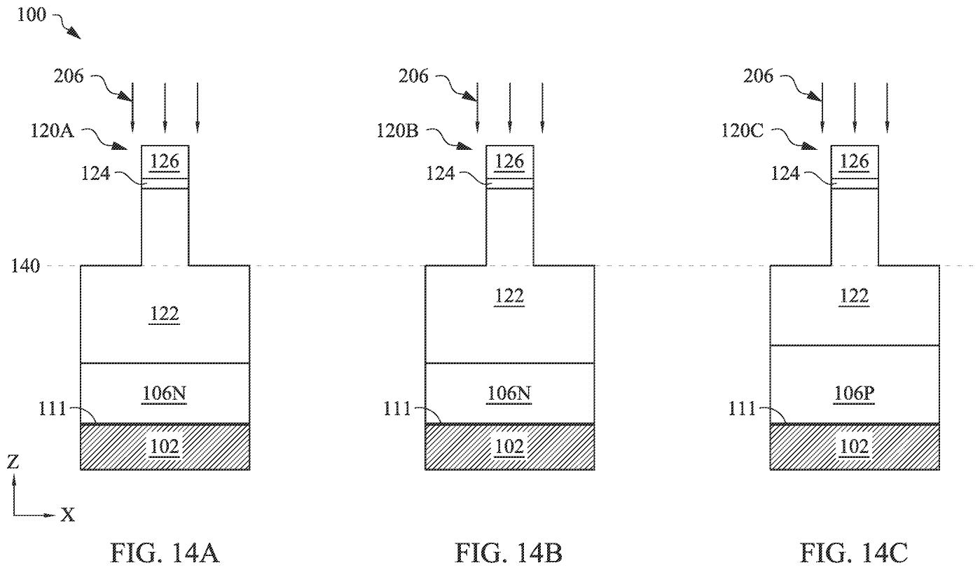

Referring to FIGS. 3 and 14A-14C, the method 400 at operation 412 performs a ME process 206 to continue patterning the gate layer 122.

In the present embodiments, the ME process 206 includes applying a combination of an O₂ treatment and a break-through (BT) etching process. Similar to the N₂ ALT, the O₂ treatment results in the formation and re-deposition of polymeric etching by-products, which may protect the profile of the etched sidewalls. The BT etching process may be implemented using similar etchant(s) to those for the ME processes 202 and 204. Additionally or alternatively, the BT etching process may be implemented using CF₄. The flux (i.e., concentration, amount, etc.) of O₂ may be adjusted during the ME process 206 to further tune the profile of the etched sidewalls of the gate layer 122. Other etching parameters, including etching power and etching time, may also be adjusted in addition to the flux. The O₂ treatment may be applied concurrently with and/or subsequently to the BT etching process.

In some embodiments, a trimming process (not depicted) is implemented subsequent to the ME process 206 to extend the sidewalls of the etched gate layer 122 to a position substantially leveled with or slightly below the top surfaces of the semiconductor fins 104N and 104P, i.e., the fin top 140. The trimming process may be implemented using similar etching gases as the ME process 202, 204, or 206.

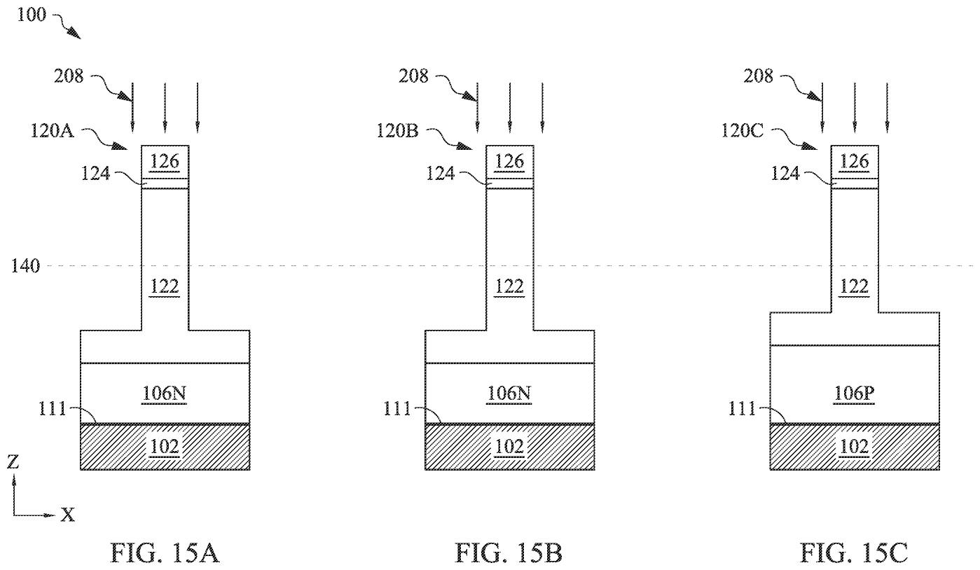

Subsequently, referring to FIGS. 15A-17C collectively, the method 400 at operations 414-42 performs a series of alternating trimming and post-etching treatment processes, i.e., the N₂ ALT.

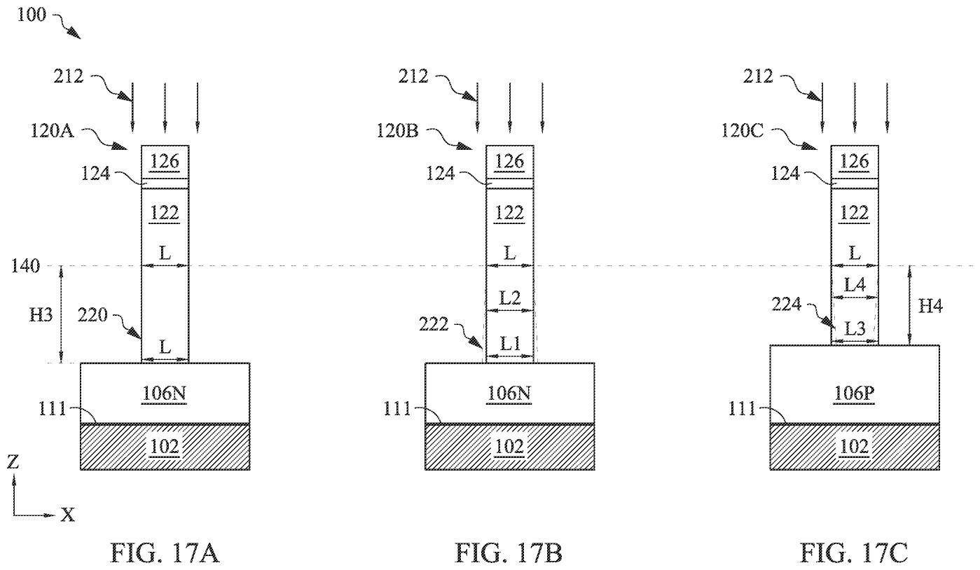

In existing implementations, the difference in step height of portions of the isolation regions 106 between the device regions 102N and 102P, i.e., the difference between H1 and H2 discussed above, may cause different degrees of lateral over-etching at the bottom portions of the gate layer 122. For example, with respect to patterning the portion 120A of the gate layer 122 between two adjacent semiconductor fins 104N, the lesser step height H1 (compared to the step height H2) allows the etching gases to penetrate more deeply along the Z direction, leading to a substantially vertical profile 220, as shown in FIG. 17A, along the sidewalls of the dummy gate structure 120, i.e., less lateral over-etching at the bottom portions of the gate layer 122, over the portion 106N. In this regard, the gate length L_{g} is substantially the same as at the bottom portion as at the top portion of the dummy gate structure 120 between two adjacent semiconductor fins 104N.

In comparison, patterning the portion 120B of the gate layer 122 between neighboring semiconductor fin 104N and dielectric fin 105 may be affected by relatively less loading of the etching gases at the bottom portions of the gate layer 122 due to the bending of the semiconductor fin 104N toward the dielectric fin 105. The limited penetration of the etching gases can cause the bottom portions of the gate layer 122 to accumulate, resulting in a footed profile 222 along the sidewalls of the dummy gate structure 120 as shown by dotted lines in FIG. 17B. In other words, the gate length L_{g} may be greater at the bottom portion than at the top portion of the dummy gate structure 120 between neighboring semiconductor fin 104N and dielectric fin 105.

With respect to patterning the portion 120C of the gate layer 122 between two adjacent semiconductor fins 104P, the greater step height H2 (compared to the step height H1) limits the loading of the etching gases along the Z direction, such that the continuous etching of the gate layer 122 over the portion 106N (due to its lower step height H1) causes lateral, rather than vertical, etching toward the bottom portions of the gate layer 122 over the portion 106P. Such lateral over-etching may form a notched (or necking) profile 224 along the sidewalls of the dummy gate structure 120 as shown by dotted lines in FIG. 17C. In other words, the gate length L_{g} is less at the bottom portion than at the top portion of the dummy gate structure 120 between two adjacent semiconductor fins 104P. In some instances, protective measures during the trimming/etching processes are only applied as the notched profile 224 forms near the bottom portions of the gate layer 122, leading to insufficient impedance to lateral over-etching.

Accordingly, the present disclosure provides a method of tuning the patterning process, particularly the trimming processes performed before reaching the bottom portions of the gate layer 122, e.g., below the fin top 140, to reduce the extent of the lateral over-etching of the gate layer 122 between two adjacent semiconductor fins 104P as well as the extent of the footing profile of the gate layer 122 between neighboring semiconductor fin 104N and dielectric fin 105. In some instances, achieving uniform sidewall profiles for the dummy gate structure, and thus the subsequently-formed metal gate structure, across different device regions leads to improved device performance with respect to gate-to-channel capacitance, device speed, drain-induced barrier lowering (DIBL), and/or device resistance. Furthermore, adjusting the sidewall profiles of the gate structure in different device regions to mitigate different structural irregularities (e.g., footing and notching) by tuning the etching processes eliminates the need to use multiple photolithography masks for patterning, reducing the cost and time associated with the device fabrication process.

In the present embodiments, the trimming processes at operations 414, 418 and 422 are configured to further etch the gate layer 122 along the Z direction toward the isolation regions 106. As the trimming processes proceed to form the bottom portions of the dummy gate structure 120, the need to maintain the profile of the etched sidewalls increases. Accordingly, each successive trimming process is implemented with a flux of O₂ greater than the previous trimming process. Additional etching gases may be incorporated in one or more of the trimming processes to limit or eliminate the formation of the notched profile 224 and the footed profile 222.

Referring to FIGS. 3 and 15A-15C, the method 400 at operation 414 performs a trimming process 208 to further etch portions of the gate layer 122 below the fin top 140.

In the present embodiments, the trimming process 208 is implemented using one or more etching gases selected from a fluorine-containing gas, a chlorine-containing gas, a bromine-containing gas, O₂, H₂, the like, or combinations thereof, as discussed in detail above. In the present embodiments, the trimming process 208 is implemented using a combination of etching gases different from that of the ME processes 202-206 to ensure sufficient etching selectivity with respect to the surrounding components (e.g., the semiconductor fins 104N and 104P). In an example embodiment, the combination of etching gases includes Cl₂, HBr, and O₂.

Subsequently, the method 400 at operation 416 performs a N₂ ALT, similar to that discussed above with respect to operation 408 to smooth and maintain the etched sidewalls of the gate layer 122.

In contrast to the ME processes 202-206, a greater flux of O₂ is applied for the trimming process 208 to maintain the profile of the etched sidewalls near the bottom portions of the gate layer 122. Additional etching protection may be gained from the N₂ ALT process at operation 416 to reduce or eliminate the notched profile 224 as shown in FIG. 17C.

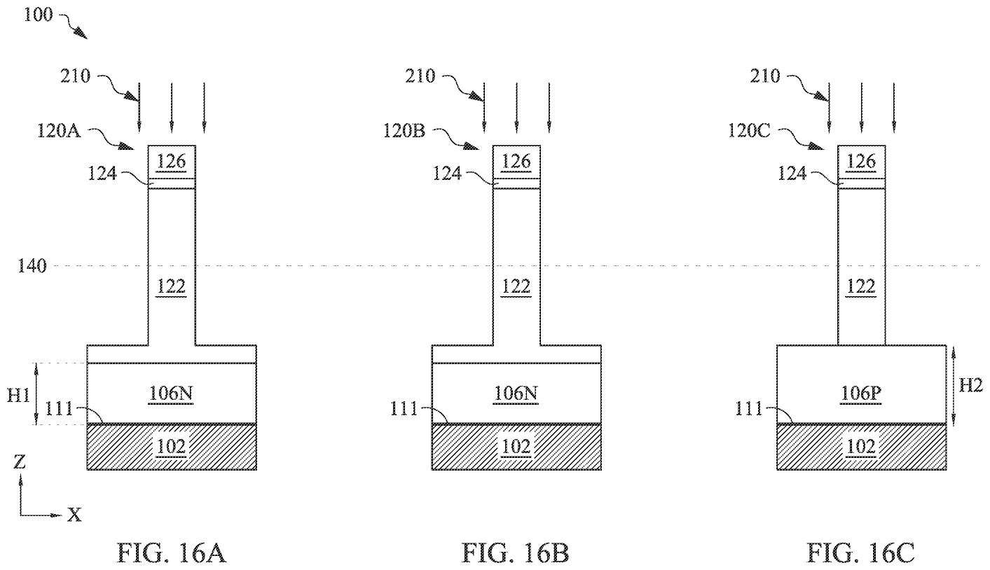

Referring to FIGS. 3 and 16A-16C, the method 400 at operation 418 performs a trimming process 210 to complete the patterning of the portion 120C of the gate layer 122 in the device region 102P, exposing the underlying portion 106P.

In some embodiments, the trimming process 210 is implemented using a similar combination of etching gases to that for the trimming process 208. Subsequently, the method 400 at operation 420 performs a N₂ ALT, similar to that discussed above with respect to operation 408 to smooth and protect the etched sidewalls of the gate layer 122.

As shown in FIGS. 16A-16C, due to the difference in the step height H1 and H2, the trimming process 210 exposes the portion 106P but not the portion 106N. Without implementing protective measures, continued etching of the gate layer 122 over the portion 106N to complete the patterning process may cause the etching gases to react with portions of the gate layer 122 along the X direction over the portion 106P, leading to the notched profile 224 as shown in FIG. 17C. Therefore, in contrast to the trimming process 208, a greater flux of O₂ is applied for the trimming process 210 to maintain the profile of the etched sidewalls and limit lateral over-etching near the bottom portions of the gate layer 122. Additional etching protection may be gained from the N₂ ALT process at operation 420 to reduce or eliminate the notched profile 224 as shown in FIG. 17C.

Referring to FIGS. 3 and 17A-17C, the method 400 at operation 422 performs a trimming process 212 to expose the portion 106N. The patterning of the gate layer 122 that includes the portions 120A, 120B, and 120C is completed.

The trimming process 212 may be implemented using one or more etching gases selected from a fluorine-containing gas, a chlorine-containing gas, a bromine-containing gas, O₂, H₂, the like, or combinations thereof, as discussed in detail above. In the present embodiments, the trimming process 212 is implemented using a combination of etching gases different from that of the trimming processes 208 and 210. In an example embodiment, the trimming process 212 may be implemented using the combination of etching gases that includes Cl₂, HBr, O₂, and CₓH_{y}F_{z}, where x>0, y≥0, and z>0. Examples of CₓH_{y}F_{z} include CF₄, CHF₃, CH₂F₂, CH₃F, the like, or combinations thereof.

The combination of the etching gases implemented at the trimming process 212 is configured to vertically and laterally trim the portions 120A and 120B of the gate layer 122 without substantially etching the portion 120C of the gate layer 122 along the lateral direction. In this regard, CₓH_{y}F_{z} is selected to allow deeper etchant penetration between neighboring semiconductor fin 104N and dielectric fin 105 due to fluorine atom's small size. The applied power of the trimming process 212 may also be reduced to encourage lateral etching to the portions 120A and/or 120B. Additionally, the flux of O₂ implemented for the trimming process 212 is also increased compared to the trimming process 210 to offer protection of the bottom portions of the portion 120C. Furthermore, polymeric by-products resulting from reacting CₓH_{y}F_{z} with material of the gate layer 122 may be re-deposited on the etched sidewalls, mitigating any potential lateral over-etching of the portion 120C and allowing the lateral trimming of the portions 120A and 120B to be implemented in a controlled manner, e.g., with reduced etching rate, compared to the previous trimming processes 208 and 210.

Still referring to FIGS. 17A-17C, the resulting portions 120A, 120B, and 120C of the dummy gate structure 120 may be formed to different dimensions. For example, using gate length L at a position corresponding to the fin top 140 as a reference, the portion 120A can be approximated to have the gate length L along its height H3 and may therefore have a substantially vertical sidewall profile.

The portion 120B, on the other hand, may be formed to have a gate length L1 along its bottom surface, where the gate length L1 may be greater than the gate length L to due to any laterally extended portions of the gate layer 122 remaining over the portion 106N. Accordingly, the portion 120B may have a footed sidewall profile that slants outward from its height H3, although the extent of such slant is mitigated by the application of one or more of the trimming processes 208-212 (e.g., the trimming process 212 discussed in detail above) toward a more uniform (i.e., vertical) sidewall profile. In some examples, a difference between the gate lengths L and L1 may be reduced by about 11% to about 57% utilizing the trimming processes 208-212 discussed above. The height H3 and height H4 (discussed below) each define a height of their respective portion of the dummy gate structure 120 extending between a top surface of their respective isolation regions 106 to the fin top 140. Furthermore, the portion 120B may be defined by a gate length L2 at a position below the fin top 140 but above the bottom surface. The gate length L2 may be different from both the gate lengths L and L1. For example, the gate length L2 is less than both the gate lengths L and L1, where a difference between the gate lengths L and L2 may be less than about 50 nm and a difference between the gate lengths L and L1 may be less than about 50 nm. In some embodiments, the dimension of the gate length L varies with respect to factors such as gate pitch and device types and may range from about 10 nm to about 200 nm.

The portion 120C may be formed to have a gate length L3 along its bottom surface, where the gate length L3 may be less than the gate length L due to lateral over-etching at the bottom portion of the portion 120C. In this regard, the gate length L3 is also less than the gate length L1 of the portion 120B. Accordingly, the portion 120C may have a notched sidewall profile that slants inward from its height H4, which is less than the height H3, although the extent of such slant is mitigated by the application of one or more of the trimming processes 208-212. Specifically, the increase in O₂ flux, the application of N₂ ALT, the controlling of the etching parameters (e.g., the etching power), or combinations thereof, are configured to reduce the extent of notching and achieve a more uniform sidewall profile. In some examples, a difference between the gate lengths L and L3 may be reduced by about 80% utilizing the trimming processes 208-212 discussed above. The gate length L4 at a position below the fin top 140 but above the bottom surface may be different from both the gate lengths L3 an L4. For example, the gate length L4 is less than both the gate lengths L and L3, where a difference between the gate lengths L and L4 may be less than about 50 nm and a difference between the gate lengths L and L3 may be less than about 50 nm.

After forming the dummy gate structure 120, referring to FIG. 2, the method 300 proceeds to operation 312 and continues the formation of the FinFET device 100. For purposes of illustration, the following operations of the method 300 are discussed in reference to the cross-section of the FinFET device 100 through the longitudinal axis of the semiconductor fin 104N and across the dummy gate structure 120.

Referring to FIGS. 2 and 18, the method 300 at operation 312 forms a number of lightly doped drain (LDD) regions 160 in the semiconductor fin 104N. The LDD regions 160 are formed on opposite sides of the dummy gate structure 120.

The LDD regions 160 may be formed by a plasma doping process. The plasma doping process may include forming and patterning masks such as a photoresist to cover the regions of the FinFET device 100 that are to be protected from the plasma doping process. The plasma doping process may implant N-type or P-type impurities in the semiconductor fin 104N to form the LDD regions 160 according to the respective conductivity type of the device. For example, P-type impurities, such as boron, may be implanted in the semiconductor fin 104N to form the LDD regions 160 for a P-type device. In another example, N-type impurities, such as phosphorus, may be implanted in the semiconductor fin 104N to form the LDD regions 160 for an N-type device. In some embodiments, the LDD regions 160 abut one of the channel regions of the FinFET device 100. Portions of the LDD regions 160 may extend under the dummy gate structure 120 and into the channel region of the FinFET device 100. For example, the LDD regions 160 may be formed after gate spacers, which will be discussed below, are formed. In some embodiments, the LDD regions 160 are omitted.

Still referring to FIG. 18, the method 300 forms gate spacers on the sidewalls of the dummy gate structure 120. In the depicted embodiments, gate spacers 150 are formed over the sidewalls of the dummy gate structure 120 and gate spacers 152 are formed over the gate spacers 150. It should be understood that any number of gate spacers can be formed on the sidewalls of the dummy gate structure 120 while remaining within the scope of the present disclosure.

The gate spacers 150 and 152 may each include any suitable dielectric material, such as silicon oxide, silicon oxycarbonitride, a low-k dielectric, silicon nitride, silicon oxynitride, silicon carbonitride, the like, or combinations thereof. Any suitable deposition method, such as thermal oxidation, CVD, ALD, the like, or combinations thereof, may be used to form the each of the gate spacers 150 and 152. In accordance with various embodiments, the gate spacers 150 and 152 are formed of different materials to provide etching selectivity in subsequent processing. The shapes and methods of forming the gate spacers 150 and 152 as illustrated in FIG. 18 (and the following figures) are merely non-limiting examples, and other shapes and formation methods are possible. These and other variations are fully intended to be included within the scope of the present disclosure.

Referring to FIGS. 2 and 19, the method 300 at operation 314 forms source/drain regions 162 in or over portions of the semiconductor fin 104N that are adjacent the dummy gate structure 120. For example, the source/drain regions 162 and the dummy gate structure 120 are alternately arranged along the X direction. To form the source/drain regions 162, in some embodiments, the semiconductor fin 104N is first recessed by, e.g., an anisotropic etching process, using the dummy gate structure 120 as an etch mask, although any other suitable etching process may also be used. The source/drain regions 162 are formed by epitaxially growing a semiconductor material in the recess, using suitable methods such as CVD, MOCVD, MBE, LPE, VPE, SEG, the like, or a combination thereof.

In some embodiments, when the resulting FinFET device 100 is an N-type FinFET, the source/drain regions 162 may include silicon and/or silicon carbide (SiC) doped with an N-type impurity (or dopant), such as phosphorous, arsenic, the like, or combinations thereof. In some embodiments, when the resulting FinFET device is a P-type FinFET, the source/drain regions 162 comprise SiGe doped with a P-type impurity, such as boron or indium.

The source/drain regions 162 may be implanted with dopants followed by an annealing process. The implanting process may include forming and patterning masks such as a photoresist to cover the regions of the FinFET device 100 that are to be protected from the implanting process. In some embodiments, the epitaxial source/drain regions 162 may be doped in situ during their growth.

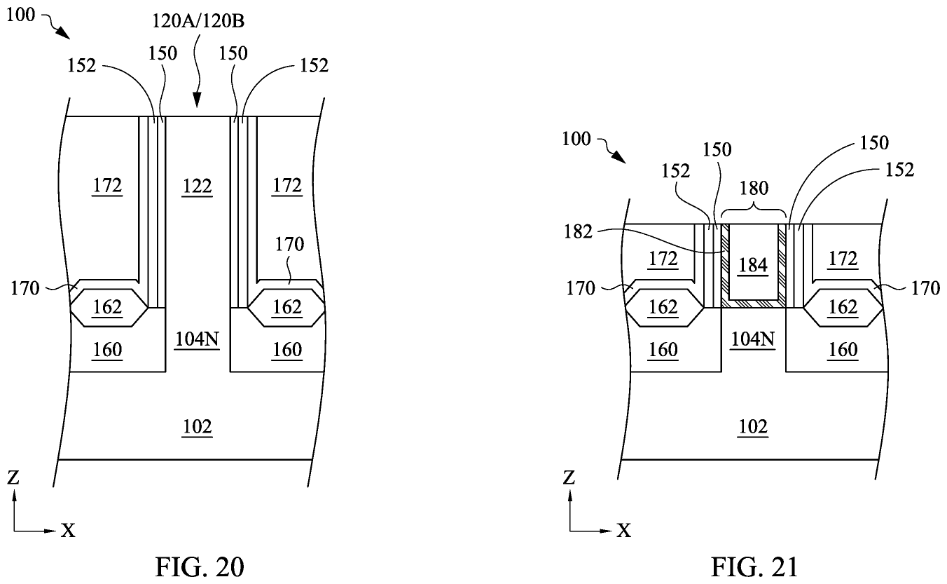

Referring to FIGS. 2 and 20, the method 300 at operation 316 forms an interlayer dielectric (ILD) layer 172 over the source/drain regions 162 and the dummy gate structure 120. In some embodiments, prior to forming the ILD layer 172, a contact etch stop layer (CESL) 170 is formed over the FinFET device 100. The CESL 170 may include a suitable material such as silicon oxide, silicon nitride, silicon oxynitride, the like, or combinations thereof, and may be formed conformally by a suitable method such as CVD, PVD, the like, or combinations thereof.

The ILD layer 172 is then formed over the CESL 170 and over the dummy gate structure 120. In some embodiments, the ILD layer 172 includes a dielectric material such as silicon oxide, a low-k dielectric material, such as PSG, BSG, BPSG, USG, the like, or combinations thereof, and may be deposited by any suitable method, such as CVD, PECVD, FCVD, spin-coating, or the like. Subsequently, a planarization process, such as a CMP process, may be performed to achieve a level upper surface for the ILD layer 172. The CMP may also remove portions of the CESL 170 and the dielectric layers 124 and 126 disposed over the dummy gate structure 120.

An example gate-last process (sometimes referred to as replacement gate process) is performed to replace the dummy gate structure 120 with a metal gate structure.

Referring to FIG. 2, the method 300 at operation 318 removes the dummy gate structure 120 to form a gate trench (not depicted). In some embodiments, to remove the dummy gate structure 120, one or more etching steps are performed to remove the gate layer 122, such that the gate trench is formed between the gate spacers 150 and 152. Each gate trench exposes the channel region of the semiconductor fin 104N.

Referring to FIGS. 2 and 21, the method 300 at operation 320 forms a metal gate structure 180 including at least a gate dielectric layer 182 and a metal gate 184 over the gate dielectric layer 182. Additional material layers, such as barrier layers and glue layers may also be included in the metal gate structure 180.

In some embodiments, the gate dielectric layer 182 includes any suitable material, such as silicon oxide, silicon nitride, a high-k dielectric material, such as an oxide or a silicate of Hf, Al, Zr, La, Mg, Ba, Ti, Pb, the like, or combinations thereof. The gate dielectric layer 182 may be formed conformally by any suitable method, such as CVD, ALD, PVD, the like, or combinations thereof.

10085| In some embodiments, the metal gate 184 includes at least a work function layer (not depicted) over the gate dielectric layer 182 and a gate electrode (not depicted) over the work function layer. The work function layer may be a P-type work function layer, an N-type work function layer, or a combination thereof. Example work function layers may include TiN, TaN, Ru, Mo, Al, ZrSi₂, MoSi₂, TaSi₂, NiSi₂, WN, Ti, Ag, TaAl, TaAlC, TiAlN, TaC, TaCN, TaSiN, Mn, Zr, the like, or combinations thereof. A work function value is associated with the material composition of the work function layer, and thus, the material of the work function layer is chosen to tune its work function value so that a target threshold voltage Vi is achieved in the device that is to be formed. The work function layer(s) may be deposited conformally by CVD, PVD, ALD, the like, or combinations thereof. The gate electrode may include a conductive material, such as W, Cu, Ru, Al, TiN, TaN, Ag, the like, or combinations thereof, and may be deposited by CVD, PVD, ALD, plating, the like, or combinations thereof, over the work function layer to fill the gate trench. One or more CMP processes are subsequently performed to planarize the top surface of the FinFET device 100.

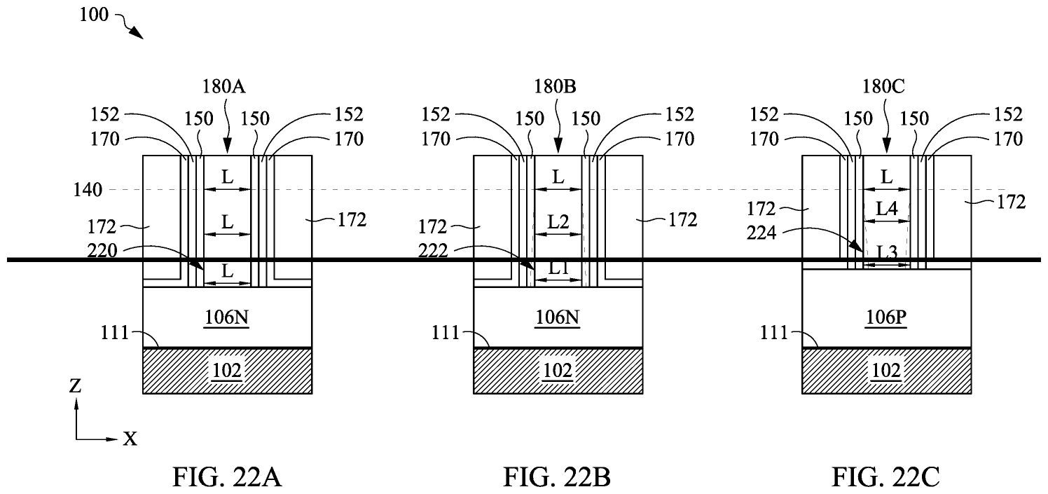

FIGS. 22A-22C illustrate portions 180A, 180B, and 180C of the metal gate structure 180, which correspond to the portions 120A, 120B, and 120C of the dummy gate structure 120 as shown FIGS. 17A-17C, respectively. The various profiles, i.e., the profiles 220, 222, and 224, of the sidewalls of the dummy gate structure 120 may be transferred to the metal gate structure 180, such that the relationships between the gate lengths L, L1, L2, L3, and L4 discussed above with respect to the dummy gate structure 120 remain application for the metal gate structure 180. In this regard, with respect to the portion 180A, which is disposed between neighboring semiconductor fins 104N, the portion 180B may include the footed profile 222 and the portion 180C may include the notched profile 224, where the portion 180B is disposed between neighboring semiconductor fin 104N and dielectric fin 105 and the portion 180C is disposed between neighboring semiconductor fins 104P. In some embodiments, the portion 180B has a substantially vertical sidewall profile, i.e., substantially without any footing, and the portion 180C has a substantially vertical sidewall profile, i.e., substantially without any notching.

Referring to FIG. 2, the method 300 at operation 322 may perform additional operations. For example, the method 300 may form a gate contact (not depicted) electrically coupled to the metal gate structure 180, a source/drain contact (not depicted) electrically coupled to one or both of the source/drain regions 162. Additionally, the method 300 may form interconnect structures, such as vias and conductive lines, electrically coupled to the gate contact(s) and/or source/drain contacts.

In an aspect of the present disclosure, a method of fabricating a semiconductor structure is disclosed. The method includes forming a semiconductor fin over a substrate. The method includes forming an isolation region around the semiconductor fin. The method includes forming a dummy gate structure over the semiconductor fin, which further includes performing a first etching process using a first etchant and subsequently performing a second etching process using a second etchant, where the first etchant is different from the second etchant in composition. The method includes forming source/drain features adjacent the dummy gate structure. The method includes replacing the dummy gate structure with a metal gate structure that is interposed between the source/drain features.

In another aspect of the present disclosure, a method of fabricating a semiconductor structure is disclosed. The method includes forming a semiconductor fin over a substrate. The method includes forming a dielectric fin over the substrate and adjacent the semiconductor fin. The method includes forming an isolation structure to separate the semiconductor fin from the dielectric fin. The method includes forming a dummy gate structure over the semiconductor fin and the dielectric fin, which further includes implementing a first etching process using a first etchant and subsequently implementing a second etching process using a second etchant, where the first etchant is different from the second etchant in composition. The method includes forming source/drain features adjacent the dummy gate structure. The method includes replacing the dummy gate structure with a metal gate structure that is interposed between the source/drain features.

In yet another aspect of the present disclosure, a semiconductor structure is disclosed. The semiconductor structure includes a first semiconductor fin extending from a substrate. The semiconductor structure includes a second semiconductor fin extending from the substrate and elongated parallel to the first semiconductor fin. The semiconductor structure includes a dielectric fin extending from the substrate and interposed between the first semiconductor fin and the second semiconductor fin. The semiconductor structure includes isolation regions surrounding the first semiconductor fin, the dielectric fin, and the second semiconductor fin. The semiconductor structure includes source/drain features over the each of the first semiconductor fin and the second semiconductor fin. The semiconductor structure includes a metal gate structure interposed between the source/drain features to engage with the first semiconductor fin, the second semiconductor fin, and the dielectric fin, where a first portion of the metal gate structure disposed between the first semiconductor fin and the dielectric fin has a first gate length along a bottom surface of the metal gate structure and a second portion of the metal gate structure disposed between the second semiconductor fin and the dielectric fin has a second gate length along the bottom surface of the metal gate structures, where the second gate length is less than the first gate length.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming a semiconductor fin over a substrate;
forming an isolation region around the semiconductor fin;
forming a dummy gate structure over the semiconductor fin, including performing a first etching process using a first etchant and subsequently performing a second etching process using a second etchant, the first etchant being different from the second etchant in composition;
forming source/drain features adjacent the dummy gate structure; and
replacing the dummy gate structure with a metal gate structure that is interposed between the source/drain features.

2. The method of claim 1, wherein the forming of the dummy gate structure further includes depositing a gate layer over the semiconductor fin and the isolation region, such that the performing of the first etching process removes a first portion of the gate layer above a top surface of the semiconductor fin and the performing of the second etching process removes a second portion of the gate layer below the top surface of the semiconductor fin.

3. The method of claim 1, wherein the forming of the dummy gate structure further includes performing a first nitrogen treatment after performing the first etching process and performing a second nitrogen treatment after performing the second etching process.

4. The method of claim 1, wherein the first etchant includes a fluorine-containing etching gas and the second etchant includes a chlorine-containing etching gas.

5. The method of claim 1, wherein both the first etchant and the second etchant include O₂, and wherein an amount of O₂ in the second etchant is greater than an amount of O₂ in the first etchant.

6. The method of claim 1, wherein the semiconductor fin includes silicon germanium, and wherein a portion of the dummy gate structure formed adjacent the semiconductor fin has a first width along a bottom surface of the dummy gate structure and a second width near a top surface of the semiconductor fin, the first width being less than the second width.

7. The method of claim 1, wherein the semiconductor fin includes silicon and is free from germanium, and wherein the forming of the dummy gate structure further includes performing a third etching process after performing the second etching process, the third etching process being performed to etch laterally along a width of the dummy gate structure along a bottom surface of the dummy gate structure.

8. The method of claim 7, wherein the performing of the third etching process is implemented using a third etchant that is different from the first etchant and the second etchant in composition.

9. The method of claim 1, further comprising forming a dielectric fin over the substrate and adjacent the semiconductor fin, such that a first portion of the isolation region having a first step height is formed adjacent a first sidewall of the dielectric fin and a second portion of the isolation region having a second step height is formed adjacent a second sidewall of the dielectric fin, the first step height being different from the second step height.

10. A method, comprising:
forming a semiconductor fin over a substrate;
forming a dielectric fin over the substrate and adjacent the semiconductor fin;
forming an isolation structure to separate the semiconductor fin from the dielectric fin;
forming a dummy gate structure over the semiconductor fin and the dielectric fin, including implementing a first etching process using a first etchant and subsequently implementing a second etching process using a second etchant, the first etchant being different from the second etchant in composition;
forming source/drain features adjacent the dummy gate structure; and
replacing the dummy gate structure with a metal gate structure that is interposed between the source/drain features.

11. The method of claim 10, wherein the first etchant includes CF₄, HBr, and O₂ and the second etchant includes Cl₂, HBr, and O₂.

12. The method of claim 11, wherein the first etching process is implemented with a lower flux of O₂ than the second etching process.

13. The method of claim 10, wherein the forming of the dummy gate structure further includes implementing a lateral trimming process to reduce a width of the dummy gate structure at a bottom surface thereof.

14. The method of claim 10, wherein a first portion of the isolation structure formed adjacent a first sidewall of the dielectric fin has a first step height and a second portion of the isolation structure formed adjacent a second sidewall of the dielectric fin opposite the first sidewall has a second step height greater than the first step height.

15. The method of claim 14, wherein the semiconductor fin is a first semiconductor fin formed from silicon, the method further comprising forming a second semiconductor fin from silicon germanium, wherein the first portion of the isolation structure is disposed between the first semiconductor fin and the dielectric fin and the second portion of the isolation structure is disposed between the dielectric fin and the second semiconductor fin.

16. A semiconductor structure, comprising:
a first semiconductor fin extending from a substrate;
a second semiconductor fin extending from the substrate and elongated parallel to the first semiconductor fin;
a dielectric fin extending from the substrate and interposed between the first semiconductor fin and the second semiconductor fin;
isolation regions surrounding the first semiconductor fin, the dielectric fin, and the second semiconductor fin;
source/drain features over the each of the first semiconductor fin and the second semiconductor fin; and
a metal gate structure interposed between the source/drain features to engage with the first semiconductor fin, the second semiconductor fin, and the dielectric fin, wherein a first portion of the metal gate structure disposed between the first semiconductor fin and the dielectric fin has a first gate length along a bottom surface of the metal gate structure and a second portion of the metal gate structure disposed between the second semiconductor fin and the dielectric fin has a second gate length along the bottom surface of the metal gate structure, the second gate length being less than the first gate length.

17. The semiconductor structure of claim 16, wherein the isolation regions include a first portion having a first step height interposed between the first semiconductor fin and the dielectric fin and a second portion having a second step height interposed between the second semiconductor fin and the dielectric fin, the first step height being less than the second step height.

18. The semiconductor structure of claim 16, wherein the first semiconductor fin includes silicon and the second semiconductor fin includes silicon germanium.

19. The semiconductor structure of claim 18, wherein the first semiconductor fin bends toward the dielectric fin and the second semiconductor fin bends away from the dielectric fin.

20. The semiconductor structure of claim 16, wherein the dielectric fin includes a multi-layered structure.
